(19) United States
(12) Patent Application Publication
(10) Pub. No.: US 2025/0151190 A1
(43) Pub. Date: May 8, 2025

(54) WIRING BOARD AND METHOD FOR MANUFACTURING WIRING BOARD

(71) Applicant: AOI ELECTRONICS CO., LTD., Kagawa (JP)

(72) Inventor: Takaaki KATO, Kagawa (JP)

(21) Appl. No.: 18/938,272

(22) Filed: Nov. 6, 2024

(30) Foreign Application Priority Data
Nov. 7, 2023 (JP) 2023-189766

(51) Int. Cl. H05K 1/02; H05K 3/12; H05K 3/46

(52) U.S. Cl. CPC H05K 1/0263; H05K 3/1283; H05K 3/4661; H05K 3/4664

(57) ABSTRACT

A wiring board includes an insulating layer and a wiring layer that is patterned, wherein the wiring layer includes: a titanium layer that is formed on the insulating layer and is mainly composed of titanium; a nickel alloy layer that is formed on the titanium layer and is mainly composed of nickel and a metal other than nickel; a plating layer that is formed on the nickel alloy layer by plating; and a metal-paste sintered layer that is formed on the plating layer.

### TECHNICAL FIELD

The present invention relates to a wiring board and a method for manufacturing a wiring board. In particular, the present invention relates to a wiring board having wiring thicker than normal wiring and a method for manufacturing the wiring board.

### BACKGROUND ART

Conventionally, there is provided a wiring board in which wiring is disposed on an insulating layer. For example, Patent Literature 1 discloses a wiring board in which a seed layer (copper layer) 51 is laminated by sputtering on an insulating layer made of insulating resin such as epoxy resin or polyimide resin, a plating layer 52 is laminated by copper plating on the seed layer 51, and a conductive layer 53 including conductive particles is laminated on the plating layer 52. Patent Literature 2 discloses a wiring board in which a copper plate is joined onto a ceramic substrate with brazing material.

### CITATION LIST

### Patent Literature

Patent Literature 1: Japanese Patent Laid-Open Publication No. 2022-119619
Patent Literature 2: Japanese Patent Laid-Open Publication No. 2023-134292

### SUMMARY

### Technical Problem

In recent years, demand for electronic components called power devices capable of handling large currents has been increasing and wiring boards having thick wiring are desired for carrying large currents in these electronic components.

In this regard, for example, Patent Literature 1 discloses that, for forming the conductive layer 53 that functions as wiring, a sintered layer 73 is formed by exposure, development, and sintering of photosensitive conductive material 70 (including photosensitive organic material and conductive particles), and exposure, development, and sintering of the photosensitive conductive material 70 is repeated to form the thick conductive layer 53 capable of carrying large currents. However, in Patent Literature 1, in order to increase the thickness of the wiring, it is necessary to repeat exposure, development, and sintering of the photosensitive conductive material 70, which results in an issue that the number of steps increases and manufacturing time and manufacturing costs increase.

In Patent Literature 2, a wiring board having thick wiring capable of carrying large currents can be provided using a sufficiently thick copper plate. However, when the copper plate is etched according to a wiring pattern, as the copper plate used is thicker, it is necessary to etch the copper plate more deeply, and at the same time the copper plate is eroded more widely in a lateral direction, which leads to an issue that the distance between adjacent wiring sections increases, preventing the wiring from being formed at high density.

An object of the present invention is to provide a wiring board having wiring thicker than normal wiring and a method for manufacturing the wiring board.

### Solution to Problem

An aspect of the present invention is summarized as a wiring board according to (1) to (8) below.

(1) A wiring board including an insulating layer and a wiring layer that is patterned, wherein the wiring layer includes: a titanium layer that is formed on the insulating layer and is mainly composed of titanium; a nickel alloy layer that is formed on the titanium layer and is mainly composed of nickel and a metal other than nickel; a plating layer that is formed on the nickel alloy layer by plating; and a metal-paste sintered layer that is formed on the plating layer.

(2) The wiring board according to (1), wherein the metal-paste sintered layer has a thickness of 300 μm or greater.

(3) The wiring board according to (1), wherein the wiring layer includes a first wiring section and a second wiring section adjacent to the first wiring section, and a closest distance between the first wiring section and the second wiring section is less than ½ of a thickness of the wiring layer.

(4) The wiring board according to (3), wherein the closest distance is 100 μm or less.

(5) The wiring board according to (1), wherein the metal-paste sintered layer and the plating layer are mainly composed of metal particles of a same metal, and the metal-paste sintered layer has a thickness that is twice a thickness of the plating layer or greater.

(6) The wiring board according to (1), wherein the plating layer is a copper plating layer that is mainly composed of copper, and the metal-paste sintered layer is a copper-paste sintered layer that is mainly composed of copper.

(7) The wiring board according to (1), wherein the insulating layer is a layer mainly including aluminum nitride or silicon nitride.

(8) The wiring board according to (1), wherein the nickel alloy layer is a nickel-titanium alloy layer that is mainly composed of nickel and titanium.

Another aspect of the present invention is summarized as a method for manufacturing a wiring board according to (9) to (13) below.

(9) A method for manufacturing a wiring board, the method including: a step of forming a titanium layer mainly composed of titanium on an insulating layer; a step of forming a nickel alloy layer mainly composed of nickel and a metal other than nickel on the titanium layer; a step of forming a plating layer on the nickel alloy layer by plating; and a step of forming a metal-paste sintered layer on the plating layer by sintering a metal paste applied in a wiring pattern.

(10) The method for manufacturing a wiring board according to (9), wherein the metal-paste sintered layer is formed by sintering the metal paste applied on the plating layer by screen printing.

(11) The method for manufacturing a wiring board according to (9), wherein the wiring pattern includes a first wiring section and a second wiring section adjacent to the first wiring section, and
a thickness of the first wiring section and the second wiring section are greater than a closest distance between the first wiring section and the second wiring section.

(12) The method for manufacturing a wiring board according to (11), wherein the closest distance is 100 μm or less.

(13) The method for manufacturing a wiring board according to (9), wherein after the metal-paste sintered layer is formed in the wiring pattern, a wiring layer including the titanium layer, the nickel alloy layer, the plating layer, and the metal-paste sintered layer is shaped according to the wiring pattern by sequentially performing a step of etching the plating layer, a step of etching the nickel alloy layer, and a step of etching the titanium layer.

### Advantageous Effects of Invention

According to the present invention, it is possible to provide a wiring board having wiring thicker than normal wiring and a method for manufacturing the wiring board.

### BRIEF DESCRIPTION OF DRAWINGS

FIG. 1 is a diagram illustrating a wiring board according to a present embodiment.

FIGS. 2A to 2D are diagrams (part 1) for explaining a method for manufacturing the wiring board according to the present embodiment.

FIGS. 3A to 3D are diagrams (part 2) for explaining the method for manufacturing the wiring board according to the present embodiment.

### DESCRIPTION OF EMBODIMENTS

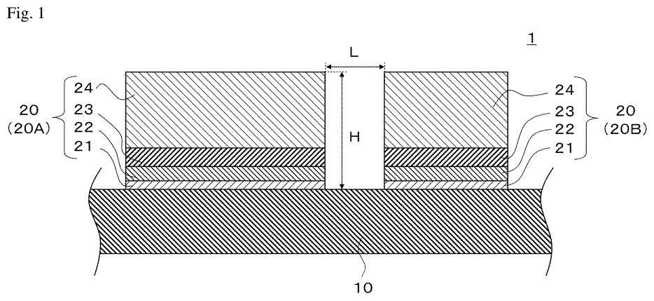

An embodiment of a wiring board of the present invention will be described with reference to the drawings. FIG. 1 is a diagram illustrating a wiring board 1 according to the present embodiment. As illustrated in FIG. 1, in the wiring board 1, a wiring layer 20 is formed on an insulating layer 10, and includes a titanium layer 21, a nickel alloy layer 22, a plating layer 23, and a metal-paste sintered layer 24 that are laminated in this order from the bottom up.

The insulating layer 10 is a layer that serves as a substrate on which the wiring layer 20 is formed in the wiring board 1, and can be made of insulating ceramic material. As the insulating layer 10, for example, nitride such as silicon nitride or aluminum nitride or oxide such as aluminum oxide can be used. In the present embodiment, an insulating layer 10 sintered in advance can be used, or an insulating layer 10 before being sintered can be used and sintered together with the metal-paste sintered layer 24 described later.

The titanium layer 21 is a layer mainly composed of titanium and is formed by, for example, sputtering titanium particles on a top surface of the insulating layer 10. In the present invention, “to be mainly composed of” means to account for half or more (fifty weight percent or more, or fifty volume percent or more) of total metal components included in each layer 21 to 24. Since the titanium layer 21 is mainly composed of titanium, titanium accounts for fifty weight percent or more, or fifty volume percent or more of the metal components included in the titanium layer 21 (the same applies to the other layers 22 to 24). The titanium layer 21 is thinner than the nickel alloy layer 22, the plating layer 23, and the metal-paste sintered layer 24, and can have a thickness of, for example, 0.01 to 0.10 μm. Titanium included in the titanium layer 21 is an active metal and has properties of spreading widely across the top surface of the insulating layer 10 and adhering strongly to the oxide or nitride insulating layer 10. In addition, in a case where the insulating layer is made of nitride, titanium reacts with nitrogen included in the insulating layer 10, thereby enhancing the adhesion between the top surface of the insulating layer 10 and the titanium layer 21.

The nickel alloy layer 22 is a layer mainly composed of nickel and a metal other than nickel such as titanium or chromium, and can be formed by sputtering material including nickel alloy particles on a top surface of the titanium layer 21. Note that a content ratio of nickel and the metal other than nickel in the nickel alloy layer 22 is not particularly limited, and the percentage of nickel in the nickel alloy can be, for example, 70% or higher and less than 99%, preferably, between 85% and 95%, inclusive. Further, although the thickness of the nickel alloy layer 22 is not particularly limited, the nickel alloy layer 22 can be thicker than the titanium layer 21 and thinner than the plating layer 23 and the metal-paste sintered layer 24. For example, the thickness of the nickel alloy layer 22 can be 0.1 to 5 μm. In the present embodiment, as the nickel alloy layer 22, a nickel-titanium alloy layer that has a thickness of 0.5 to 1.5 μm and is mainly composed of nickel and titanium is formed.

In the present embodiment, laminating the nickel alloy layer 22 on the titanium layer 21 allows for efficient plating at the time of forming the plating layer 23 on a top surface of the nickel alloy layer 22. That is, if the plating layer 23 is formed by plating directly on the top surface of the titanium layer 21, easy-oxidation property of the titanium layer 21 would, in some cases, hinder efficient plating. In contrast, in the present embodiment, oxidation of titanium on the surface of the titanium layer can be suppressed by forming the nickel alloy layer 22 on the titanium layer 21, 20 and the nickel alloy layer 22 also functions as a seed layer, allowing for efficient plating for forming the plating layer 23.

The plating layer 23 is a layer mainly composed of metal particles used for wiring such as copper, aluminum, silver, tungsten, or molybdenum, and is formed on the nickel alloy layer 22 by plating on the top surface of the nickel alloy layer 22. In the present embodiment, from the viewpoint of manufacturing costs, a copper plating layer is formed as the plating layer 23 through a copper-plating process. Further, the plating layer 23 may be an electrolytic plating layer formed through an electrolytic plating process, or may be a non-electrolytic plating layer formed through a non-electrolytic plating process. Although the thickness of the plating layer 23 is not particularly limited, the plating layer 23 can be formed to be thicker than the titanium layer 21 and the nickel alloy layer 22 and thinner than the metal-paste sintered layer 24. For example, the thickness of the plating layer 23 can be 5 to 10 μm.

Like the plating layer 23, the metal-paste sintered layer 24 is a layer mainly composed of metal particles used for wiring such as copper, aluminum, silver, tungsten, or molybdenum. The metal-paste sintered layer 24 is formed to be thick so that it can carry large currents. The metal-paste sintered layer 24 is formed by laminating a paste containing the metal particles on the plating layer 23 and sintering the paste. For example, as the plating layer 23, a copper plating layer mainly composed of copper particles can be formed, and as the metal-paste sintered layer 24, a copper-paste sintered layer can be formed in which a copper paste mainly composed of copper particles is laminated and sintered. Note that, when the paste in which the metal particles are added to an organic solvent is used as a metal paste, the organic solvent volatilizes at the time of sintering, resulting in the formation of the metal-paste sintered layer 24 constituting the metal particles.

The way to apply the metal paste that makes up the patterned metal-paste sintered layer 24 is not particularly limited and, for example, a printing method such as screen printing or offset printing or an application method using a dispenser can be used for lamination. However, the screen printing is preferable from the viewpoint of the breadth of the printing area and film thickness uniformity. This is because the screen printing can handle even a metal paste with relatively high viscosity and allows for forming a predetermined wiring pattern at one time. Further, the thickness of the metal-paste sintered layer 24 can be adjusted appropriately according to a desired use, and thick wiring with a thickness of, for example, 100 to 3000 μm (preferably, 300 to 1500 μm or 500 to 2000 μm) can be formed. Therefore, in the wiring board 1 according to the present embodiment, the thickness of the wiring layer 20 can be 300 μm or greater, and the wiring board 1 having wiring capable of carrying large currents can be manufactured.

In order to increase the thickness of the metal-paste sintered layer 24, screen printing can be performed more than once. In this case, after a plurality of layers of the metal paste are applied, the layered metal paste may be sintered at one time. Alternatively, the sintering may be performed each time the metal paste is applied by screen printing. If many layers of the metal paste are applied without sintering, the metal-paste sintered layer 24 may lose its shape. Thus, it is preferable to perform screen printing of the metal paste multiple times as far as the metal-paste sintered layer 24 does not lose its shape and perform sintering, and then repeat the multiple screen printing of the metal paste and the sintering in a similar manner.

Further, as illustrated in FIG. 1, in the wiring board 1 according to the present embodiment, the thickness H of the wiring layer 20 is greater than the closest distance L between a first wiring section 20A and a second wiring section 20B that are adjacent to each other. This is achieved in the present embodiment not only because repeatedly laminating the metal paste by screen printing allows the thickness of the metal-paste sintered layer 24 to increase when manufacturing the patterned metal-paste sintered layer 24, but also because no etching is necessary when forming the metal-paste sintered layer 24 in a wiring pattern and thus dissolution of each wiring section can be suppressed, preventing the distance between adjacent patterned wiring sections from increasing. As a result, in the present embodiment, it is possible to provide the wiring board 1 in which the thick wiring is formed at high density, specifically, the wiring board 1 having the wiring layer in which the inter-wiring distance is reduced to less than ½ of the thickness of the wiring layer, for example, the inter-wiring distance is reduced to ⅓ or less of the thickness of the wiring or to ¼ or less of the thickness of the wiring, or to a range of less than ¼ to about ⅙ of the thickness of the wiring. For example, in the present embodiment, it is possible to provide the wiring having a thickness of 300 μm in such a wiring pattern that the closest distance between adjacent wiring sections is 100 μm or less, for example, the closest distance is 50 μm. In the present embodiment, by forming the plating layer 23 on the top surface of the nickel alloy layer 22 through plating and forming the metal-paste sintered layer 24 on the plating layer 23, adhesion of the metal-paste sintered layer 24 can be enhanced compared with the case where the metal-paste sintered layer 24 is formed directly on the nickel alloy layer 22. In particular, in a case where the plating layer 23 and the metal-paste sintered layer 24 are mainly composed of the same metal, the metal-paste sintered layer 24 is integrated with the plating layer 23 when the metal-paste sintered layer 24 is sintered, which can enhance the adhesion of the metal-paste sintered layer 24 to the plating layer 23.

### [Manufacturing Method]

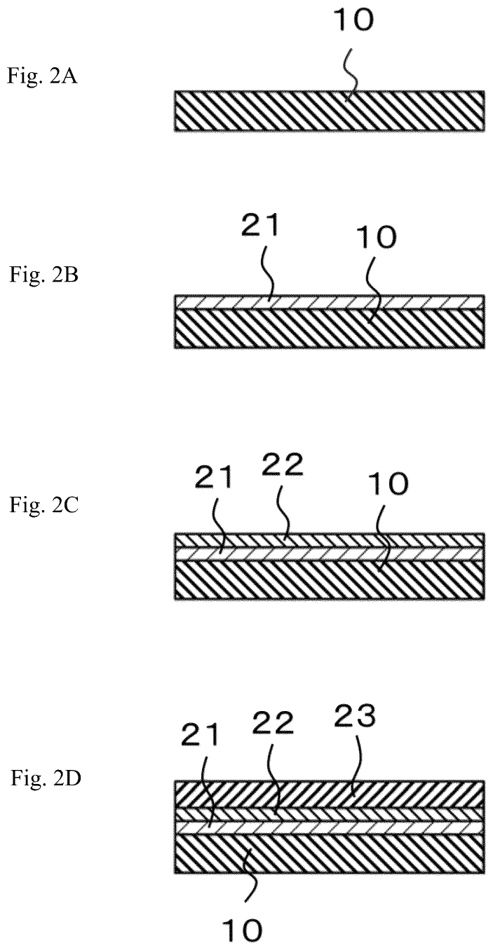

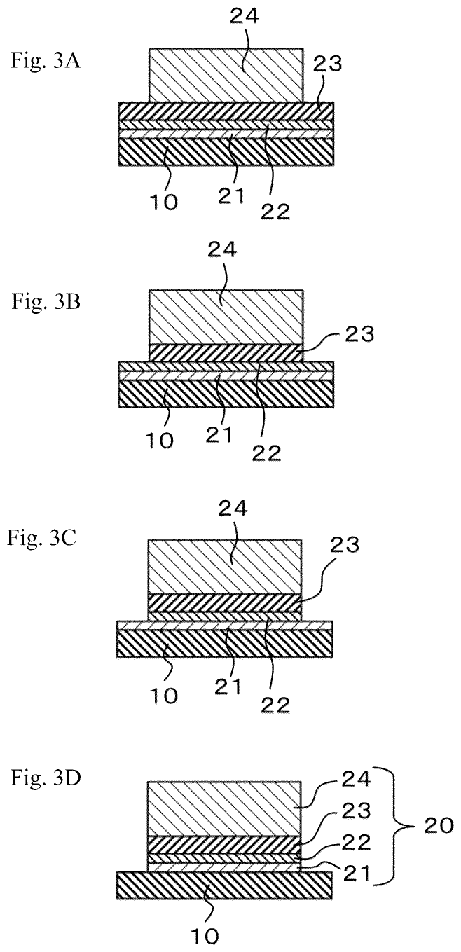

Next, a method for manufacturing the wiring board 1 according to the present embodiment will be described with reference to FIGS. 2A to 2D and 3A to 3D. FIGS. 2A to 2D and 3A to 3D are diagrams for explaining the method for manufacturing the wiring board 1 according to the present embodiment. Hereinafter, an explanation will be given using an example where the wiring board 1 has an aluminum nitride substrate as the insulating layer 10, a nickel-titanium layer as the nickel alloy layer 22, a copper plating layer as the plating layer 23, and a copper-paste sintered layer as the metal-paste sintered layer 24.

First, as illustrated in FIG. 2A, the insulating layer 10 is prepared. In the present embodiment, as the insulating layer 10, a sintered aluminum nitride substrate is prepared. Then, as illustrated in FIG. 2B, the titanium layer 21 is formed by sputtering material including titanium particles over the entire wiring area on the top surface of the prepared insulating layer 10. Next, as illustrated in FIG. 2C, a nickel-titanium alloy layer is formed as the nickel alloy layer 22 by sputtering material including titanium particles and nickel particles over the entire wiring area on the top surface of the titanium layer 21. Further, as illustrated in FIG. 2D, electrolytic copper plating is performed using the nickel alloy layer 22 as a seed layer to form an electrolytic copper plating layer as the plating layer 23 over the entire wiring area on the top surface of the nickel alloy layer 22. Note that the sputtering process and the plating process described above can be carried out by a publicly-known method.

Subsequently, as illustrated in FIG. 3A, a copper paste is laminated by screen printing in a wiring pattern and is sintered on the plating layer 23, thereby forming the metal-paste sintered layer 24. In the present embodiment, formation of a metal paste layer having a film thickness of several tens of micrometers by one screen printing is repeated more than once to form a thick metal paste layer and the thick metal paste layer is sintered, allowing the thickness of the wiring layer 20 to be 300 μm or greater, for example. As described later, because a top surface of the formed metal paste layer is dissolved by etching, it is necessary to form the metal paste layer with its thickness additionally increased by an amount to be dissolved by the etching.

While in FIGS. 2B to 2D, the sputtering and plating processes result in the formation of the titanium layer 21, the nickel alloy layer 22, and the plating layer 23 over the entire wiring area on the top surface of the insulating layer 10. While in FIG. 3A, the screen printing allows for the formation of the metal-paste sintered layer 24 in the wiring pattern of the wiring layer 20. Subsequently, in FIGS. 3B to 3D, the titanium layer 21, the nickel alloy layer 22, and the plating layer 23 that have been formed over the entire insulating layer 10 undergo removal processes according to the wiring pattern of the wiring layer 20.

That is, first, as illustrated in FIG. 3B, an exposed portion of the plating layer 23 on which the metal-paste sintered layer 24 is not laminated is removed by etching for the plating layer 23 (in the present embodiment, copper etching). Note that, when the plating layer 23 and the metal-paste sintered layer 24 are layers mainly composed of copper particles, the metal-paste sintered layer 24 is also dissolved along with the plating layer 23 by copper etching. However, since the metal-paste sintered layer 24 is greater in thickness than the plating layer 23 (has a thickness twice the thickness of the plating layer 23 or greater), even when the exposed portion of the plating layer 23 is removed, the metal-paste sintered layer 24 remains in a state where its thickness is greater than the thickness of the plating layer 23 under the metal-paste sintered layer 24.

Next, as illustrated in FIG. 3C, the wiring layer 20 can be formed into the wiring pattern by etching for the nickel alloy layer 22 (in the present embodiment, nickel-titanium etching) and then etching for the titanium layer 21. As a result, as illustrated in FIG. 3D, the wiring board 1 can be manufactured in which the wiring layer 20 having the predetermined wiring pattern is formed on the insulating layer 10.

As described above, the wiring board 1 according to the present embodiment is a wiring board 1 including an insulating layer 10 and a wiring layer 20, in which the wiring layer 20 includes: a titanium layer 21 that is formed on the insulating layer 10 and is mainly composed of titanium; a nickel alloy layer 22 that is formed on the titanium layer 21 and is mainly composed of nickel and a metal other than nickel; a plating layer 23 that is formed on the nickel alloy layer 22 by plating; and a metal-paste sintered layer 24 that is formed on the plating layer. Particularly, since the wiring board 1 according to the present embodiment has the metal-paste sintered layer 24 formed by sintering a metal paste applied in a wiring pattern by screen printing, thick wiring capable of carrying large currents can be efficiently manufactured by simply repeating screen printing.

That is, conventionally, for forming thick wiring, a method of repeating exposure, development, and sintering of photosensitive conductive material or a method of repeating plating and etching for laminating a plating film is performed. However, the former method requires repeating a plurality of steps such as exposure, development, and sintering of the photosensitive conductive material, and the latter method requires repeating a plurality of steps such as resist formation, plating, and etching, leading to an issue that the number of steps and the manufacturing time increase. In contrast, in the present embodiment, for increasing the thickness of wiring, it is sufficient to simply repeat screen printing of the metal paste, allowing for reduction in the number of steps and the manufacturing time compared to the conventional methods, and thus thick wiring can be efficiently manufactured.

Further, conventionally, in the method of repeating plating and etching for laminating a plating film, side surfaces of wiring sections are dissolved due to repeated etching. This would lead to an issue that the distance between a section of the wiring layer 20 and another adjacent section of the wiring layer 20 (distance L in FIG. 1) becomes longer, preventing sections of the wiring layer 20 from being formed at high density. In contrast, in the present embodiment, since an etching process by which the metal-paste sintered layer 24 is dissolved is carried out only once when the plating layer 23 is etched, the dissolution of side surfaces of the wiring layer 20 can be suppressed and a circuit of the wiring layer 20 can be formed at high density. Moreover, conventionally, in a case where a copper plate is used to form a wiring layer, alignment of the copper plate on the substrate is sometimes difficult. However, in the present embodiment, by screen-printing the metal paste in the wiring pattern, the metal-paste sintered layer 24 according to the wiring pattern can be easily formed. In addition, compared to the case where the metal paste is applied using a dispenser, in the present embodiment, the wiring board 1 can be more efficiently manufactured since printing the metal paste in the wiring pattern by screen printing allows the metal-paste sintered layer 24 according to the wiring pattern to be laminated at one time.

In addition, in the present embodiment, by forming the titanium layer 21, the nickel alloy layer 22, the plating layer 23, and the metal-paste sintered layer 24 on the insulating layer 10 in this order, the metal-paste sintered layer 24 can be laminated with high adhesion even on the insulating layer 10 made of ceramic material. Here, if the metal-paste sintered layer 24 is formed by laminating and sintering the metal paste directly on the insulating layer 10 made of ceramic material, when the thickness of the wiring is increased, there is a risk that the metal-paste sintered layer 24 peels off from the insulating layer 10 due to low adhesion between the insulating layer 10 and the metal-paste sintered layer 24. In contrast, in the titanium layer 21, titanium spreads widely across the insulating layer 10 made of ceramic material, thereby enhancing adhesion between the insulating layer 10 and the titanium layer 21. In the nickel alloy layer 22, nickel has high affinity with titanium of the titanium layer 21 and can suppress oxidation of titanium on the layer surface, thereby enhancing adhesion to the plating layer 23. Further, adhesion of the plating layer 23 to the metal-paste sintered layer 24 can be enhanced by integrally sintering the plating layer 23 and the metal-paste sintered layer 24. When the plating layer 23 and the metal-paste sintered layer 24 are mainly composed of the same metal, adhesion between the plating layer 23 and the metal-paste sintered layer 24 can be further enhanced. Therefore, in the wiring board 1 according to the present embodiment, the metal-paste sintered layer 24 has high adhesion and it is possible to prevent the wiring layer 20 including the metal-paste sintered layer 24 from peeling off from the insulating layer 10.

Although the preferred embodiment of the present invention has been described above, the technical scope of the present invention is not limited to the descriptions of the above embodiment. Various alterations and modifications can be applied to the above embodiment, and such altered or modified modes also fall within the technical scope of the present invention.

For example, although a configuration is illustrated in which the nickel alloy layer 22 is formed as a seed layer in the above embodiment, the present invention is not limited to this configuration. For example, a configuration is also possible in which, instead of nickel, a palladium layer mainly composed of palladium and a metal other than palladium such as titanium or chromium is formed.

### REFERENCE SIGNS LIST

1: wiring board
10: insulating layer
20: wiring layer
21: titanium layer
22: nickel alloy layer
23: plating layer
24: metal-paste sintered layer

1. A wiring board comprising an insulating layer and a wiring layer that is patterned,
wherein the wiring layer includes:
a titanium layer that is formed on the insulating layer and is mainly composed of titanium;
a nickel alloy layer that is formed on the titanium layer and is mainly composed of nickel and a metal other than nickel;
a plating layer that is formed on the nickel alloy layer by plating; and
a metal-paste sintered layer that is formed on the plating layer.

2. The wiring board according to claim 1, wherein the metal-paste sintered layer has a thickness of 300 μm or greater.

3. The wiring board according to claim 1, wherein the wiring layer includes a first wiring section and a second wiring section adjacent to the first wiring section, and
a closest distance between the first wiring section and the second wiring section is less than ½ of a thickness of the wiring layer.

4. The wiring board according to claim 3, wherein the closest distance is 100 μm or less.

5. The wiring board according to claim 1, wherein the metal-paste sintered layer and the plating layer are mainly composed of metal particles of a same metal, and
the metal-paste sintered layer has a thickness that is twice a thickness of the plating layer or greater.

6. The wiring board according to claim 1, wherein the plating layer is a copper plating layer that is mainly composed of copper, and
the metal-paste sintered layer is a copper-paste sintered layer that is mainly composed of copper.

7. The wiring board according to claim 1, wherein the insulating layer is a layer mainly including aluminum nitride or silicon nitride.

8. The wiring board according to claim 1, wherein the nickel alloy layer is a nickel-titanium alloy layer that is mainly composed of nickel and titanium.

9. A method for manufacturing a wiring board, the method comprising:
a step of forming a titanium layer mainly composed of titanium on an insulating layer;
a step of forming a nickel alloy layer mainly composed of nickel and a metal other than nickel on the titanium layer;
a step of forming a plating layer on the nickel alloy layer by plating; and
a step of forming a metal-paste sintered layer on the plating layer by sintering a metal paste applied in a wiring pattern.

10. The method for manufacturing a wiring board according to claim 9, wherein the metal-paste sintered layer is formed by sintering the metal paste applied on the plating layer by screen printing.

11. The method for manufacturing a wiring board according to claim 9, wherein the wiring pattern includes a first wiring section and a second wiring section adjacent to the first wiring section, and
a thickness of the first wiring section and the second wiring section are greater than a closest distance between the first wiring section and the second wiring section.

12. The method for manufacturing a wiring board according to claim 11, wherein the closest distance is 100 μm or less.

13. The method for manufacturing a wiring board according to claim 9, wherein after the metal-paste sintered layer is formed in the wiring pattern, a wiring layer including the titanium layer, the nickel alloy layer, the plating layer, and the metal-paste sintered layer is shaped according to the wiring pattern by sequentially performing a step of etching the plating layer, a step of etching the nickel alloy layer, and a step of etching the titanium layer.
